(19) United States
(12) Patent Application Publication
(10) Pub. No.: US 2026/0118887 A1
(43) Pub. Date: Apr. 30, 2026

(54) GROUND-BASED TRANSPORT APPARATUS AND LOGISTICS PROCESSING SYSTEM INCLUDING THE SAME

(71) Applicant: SAMSUNG ELECTRONICS CO., LTD., Suwon-si (KR)

(72) Inventors: Gyeong Dam BAEK, Suwon-si (KR); Ji Won YOON, Suwon-si (KR); Wang Hyeon SON, Cheonan-si (KR); Seung Jun LEE, Hwaseong-si (KR); Kun Jin RYU, Suwon-si (KR); Seung Hyuk BAEK, Suwon-si (KR); Seung-Jun LEE, Suwon-si (KR); Youn Boo JUNG, Suwon-si (KR); Jae Hyuk CHA, Suwon-si (KR); Ji Min CHOI, Suwon-si (KR)

(73) Assignees: SAMSUNG ELECTRONICS CO., LTD., Suwon-si (KR); SEMES CO., LTD., Cheonan-si (KR)

(21) Appl. No.: 19/244,514

(22) Filed: Jun. 20, 2025

(30) Foreign Application Priority Data
Oct. 28, 2024 (KR) 10-2024-0148239

(51) Int. Cl. G05D 1/667; G05D 1/661; G05D 1/689; G05D 107/70; G05D 109/10; G05D 111/10; G05D 111/50; G06K 7/14

(52) U.S. Cl. CPC G05D 1/667; G05D 1/661; G05D 1/6895; G06K 7/1417; G05D 2107/70; G05D 2109/10; G05D 2111/10; G05D 2111/54

(57) ABSTRACT

A ground-based transport apparatus for transporting a container in a semiconductor manufacturing plant includes a driving controller configured to move the ground-based transport apparatus on a ground of the semiconductor manufacturing plant, a housing on the driving controller, a shelf structure in the housing and including a plurality of shelves, and a manipulator arm assembly in the housing and spaced apart from the shelf structure. The manipulator arm assembly is configured to remove the container from a first shelf of the plurality of shelves, and set the container on a second shelf of the plurality of shelves. The driving controller is further configured to transport the container between a plurality of facilities, and store the container in a ground-based storage apparatus disposed on the ground of the semiconductor manufacturing plant. Each facility of the plurality of facilities includes a substrate treating apparatus. The container stores a substrate.

### CROSS-REFERENCE TO RELATED APPLICATIONS

This application claims benefit of priority under 35 U.S.C. § 119 to Korean Patent Application No. 10-2024-0148239, filed on Oct. 28, 2024 in the Korean Intellectual Property Office, the disclosure of which is incorporated by reference herein in its entirety.

### BACKGROUND

### 1. Field

The present disclosure relates generally to ground-based transport apparatuses, and more particularly, to a ground-based transport apparatus for carrying a container in which a substrate is received in the semiconductor manufacturing plant, and a logistics processing system including the same.

### 2. Description of Related Art

When a substrate is processed to produce a semiconductor, the substrate may be moved to a facility that may perform one or more processes such as, but not limited to, a photo process, an etching process, a cleaning process, a deposition process, an ion implantation process, or the like, while the substrate is stored in a container (e.g., a front opening unified pod (FOUP)).

An overhead transport apparatus (e.g., an overhead hoist transporter (OHT)) and/or a ground-based transport apparatus (e.g., autonomous mobile robot (AMR) or an automated guided vehicle (AGV)) may be disposed within a semiconductor manufacturing plant to transport the container. However, as numerous facilities may be arranged in a limited space on the ground, there may be a limitation on a work space. Accordingly, an overhead transport apparatus may be used for transporting the container.

### SUMMARY

One or more example embodiments of the present disclosure provide a ground-based transport apparatus capable of overcoming a workspace constraint and a logistics processing system including the same.

According to an aspect of the present disclosure, a ground-based transport apparatus for transporting a container in a semiconductor manufacturing plant includes a driving controller configured to move the ground-based transport apparatus on a ground of the semiconductor manufacturing plant, a housing on the driving controller, a shelf structure in the housing and including a plurality of shelves, and a manipulator arm assembly in the housing and spaced apart from the shelf structure. The manipulator arm assembly is configured to remove the container from a first shelf of the plurality of shelves, and set the container on a second shelf of the plurality of shelves. The driving controller is further configured to transport the container between a plurality of facilities, and store the container in a ground-based storage apparatus disposed on the ground of the semiconductor manufacturing plant. Each facility of the plurality of facilities includes a substrate treating apparatus. The container stores a substrate.

According to an aspect of the present disclosure, a logistics processing system includes a substrate treating apparatus configured to treat a substrate, an overhead storage apparatus configured to store a container storing the substrate, the overhead storage apparatus being installed on a ceiling of a semiconductor manufacturing plant, a ground-based storage apparatus installed on a ground of the semiconductor manufacturing plant and configured to store the container, an overhead transport apparatus configured to move along a rail installed on the ceiling of the semiconductor manufacturing plant and to transport the container, and a ground-based transport apparatus configured to move on the ground of the semiconductor manufacturing plant and to transport the container. The ground-based transport apparatus includes a driving controller configured to move the ground-based transport apparatus on the ground of the semiconductor manufacturing plant, a housing on the driving controller, a shelf structure in the housing and including a plurality of shelves, and a manipulator arm assembly in the housing and spaced apart from the shelf structure. The manipulator arm assembly is configured to remove the container from a first shelf of the plurality of shelves, and set the container on a second shelf of the plurality of shelves. The driving controller is further configured to transport the container between a plurality of facilities and the ground-based storage apparatus. Each facility of the plurality of facilities includes the substrate treating apparatus.

According to an aspect of the present disclosure, a ground-based transport apparatus for transporting a container in a semiconductor manufacturing plant includes a driving controller configured to move the ground-based transport apparatus on a ground of the semiconductor manufacturing plant, a housing on the driving controller, a shelf structure in the housing and including a plurality of shelves, and a manipulator arm assembly in the housing and spaced apart from the shelf structure. The manipulator arm assembly is configured to remove the container from a first shelf of the plurality of shelves, and set the container on a second shelf of the plurality of shelves. The driving controller is configured to transport the container between a plurality of facilities, each facility of the plurality of facilities including a substrate treating apparatus, the container storing a substrate, and store the container in a ground-based storage apparatus disposed on the ground of the semiconductor manufacturing plant. The driving controller includes a code reader configured to identify an identification code attached to each facility of the plurality of facilities, a first distance measuring sensor configured to measure a first distance between the ground-based transport apparatus and a facility of the plurality of facilities, and a second distance measuring sensor configured to measure a second distance between the ground-based transport apparatus and the facility. The second distance measuring sensor is adjacent to the first distance measuring sensor. The driving controller is configured to dock the ground-based transport apparatus with the facility based on the identification code, the first distance, and the second distance. The identification code includes at least one of a plurality of vertical codes attached to an upper portion of a front surface plate of the facility or a horizontal code attached to a side surface of the front surface plate of the facility. The driving controller is configured to, based on the identification code including the plurality of vertical codes, correct a docking posture of the ground-based transport apparatus based on a first angle between a first line segment and a second line segment, and, based on the identification code including the horizontal code, correct the docking posture based on a second angle between a third line segment and a fourth line segment. The first line segment couples a first vertical code of the plurality of vertical codes with a second vertical code of the plurality of vertical codes. The second line segment is parallel to a front surface of the driving controller. The third line segment couples the first distance measuring sensor with the second distance measuring sensor. The fourth line segment is parallel to the front surface of the front surface plate of the facility.

It should be noted that the effects of the present disclosure are not limited to those described above, and other effects of the present disclosure may be apparent from the following description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the attached drawings, in which:

FIG. 1 is a first example diagram for illustrating the concept of a logistics processing system, according to some embodiments of the present disclosure;

FIG. 2 is a second example diagram for illustrating the concept of the logistics processing system, according to some embodiments of the present disclosure;

FIG. 3 is a first example diagram for illustrating a structure of the ground-based transport apparatus of the logistics processing system, according to some embodiments of the present disclosure;

FIG. 4 is a first example diagram for illustrating a driving module of the ground-based transport apparatus, according to some embodiments of the present disclosure;

FIG. 5 is a second example diagram for illustrating a driving module of the ground-based transport apparatus, according to some embodiments of the present disclosure;

FIG. 6 is a first example diagram for illustrating the housing and the shelf module of the ground-based transport apparatus, according to some embodiments of the present disclosure;

FIG. 7 is a second example diagram for illustrating the housing and the shelf module of the ground-based transport apparatus, according to some embodiments of the present disclosure;

FIG. 8 is a second example diagram for illustrating a structure of the ground-based transport apparatus of the logistics processing system, according to some embodiments of the present disclosure;

FIG. 9 is a first example diagram for illustrating a manipulator module of the ground-based transport apparatus, according to some embodiments of the present disclosure;

FIG. 10 is a second example diagram for illustrating a manipulator module of the ground-based transport apparatus, according to some embodiments of the present disclosure;

FIG. 11 is a third example diagram for illustrating a manipulator module of the ground-based transport apparatus, according to some embodiments of the present disclosure;

FIG. 12 is a first example diagram for illustrating a docking sequence of a ground-based transport apparatus, according to some embodiments of the present disclosure;

FIG. 13 is a second example diagram for illustrating a docking sequence of the ground-based transport apparatus, according to some embodiments of the present disclosure;

FIG. 14 is a third example diagram for illustrating a docking sequence of the ground-based transport apparatus, according to some embodiments of the present disclosure;

FIG. 15 is a fourth example diagram for illustrating a docking sequence of the ground-based transport apparatus, according to some embodiments of the present disclosure;

FIG. 16 is a fifth example diagram for illustrating a docking sequence of the ground-based transport apparatus, according to some embodiments of the present disclosure;

FIG. 17 is a sixth example diagram for illustrating a docking sequence of the ground-based transport apparatus, according to some embodiments of the present disclosure;

FIG. 18 is a first example diagram for illustrating a handling sequence of a ground-based transport apparatus, according to some embodiments of the present disclosure;

FIG. 19 is a second example diagram for illustrating a handling sequence of the ground-based transport apparatus, according to some embodiments of the present disclosure;

FIG. 20 is a third example diagram for illustrating a handling sequence of the ground-based transport apparatus, according to some embodiments of the present disclosure;

FIG. 21 is a fourth example diagram for illustrating a handling sequence of a ground-based transport apparatus, according to some embodiments of the present disclosure; and

FIG. 22 is a fifth example diagram for illustrating a handling sequence of the ground-based transport apparatus, according to some embodiments of the present disclosure.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it may indicate that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

The embodiments herein may be described and illustrated in terms of blocks, as shown in the drawings, which carry out a described function or functions. These blocks, which may be referred to herein as units or modules or the like, or by names such as, but not limited to, device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, or the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

Hereinafter, embodiments of the present disclosure are described with reference to the accompanying drawings.

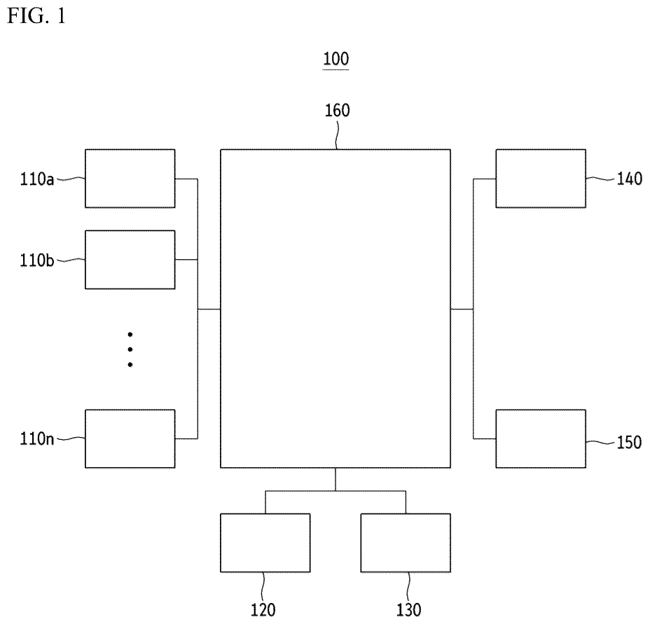

FIG. 1 is a first example diagram for illustrating the concept of a logistics processing system, according to some embodiments of the present disclosure. Referring to FIG. 1, a logistics processing system 100 may be configured to include a plurality of substrate treating apparatuses (e.g., a first substrate treating apparatus 110a, a second substrate treating apparatus 110b, to an n-th substrate treating apparatus 110n, where n is a positive integer greater than one (1), hereinafter generally referred to as “110”), one or more container storage apparatuses (e.g., an overhead storage apparatus 120 and a ground-based storage apparatus 130), and one or more container transport apparatuses (e.g., an overhead transport apparatus 140 and a ground-based apparatus 150).

The logistics processing system 100 may be built and/or located within a semiconductor manufacturing plant. The logistics processing system 100 may be embodied as a logistics automation system. The plurality of substrate treating apparatuses 110, the one or more container storage apparatuses 120 and 130, and the one or more container transport apparatuses 140 and 150 of the logistics processing system 100 may contribute to the production of a semiconductor.

The plurality of substrate treating apparatuses 110 may perform different substrate treating processes to produce the semiconductor. For example, the first substrate treating apparatus 110a may perform an etching process. The first substrate treating apparatus 110a may be provided in a plural manner in the semiconductor manufacturing plant, or may be provided in a single manner in the semiconductor manufacturing plant. As another example, the second substrate treating apparatus 110b may perform a cleaning process. The second substrate treating apparatus 110b may be provided in a plural manner in the semiconductor manufacturing plant, or may be provided in a single manner in the semiconductor manufacturing plant. As another example, the n-th substrate treating apparatus 110n may perform a photolithography process. The n-th substrate treating apparatus 110n may be provided in a plural manner in the semiconductor manufacturing plant, or may be provided in a single manner in the semiconductor manufacturing plant.

In an embodiment, the logistics processing system 100 may include various types of substrate treating apparatuses, such as, but not limited to, a substrate treating apparatus for performing deposition and/or ion implantation, a substrate treating apparatus for performing packaging, a substrate treating apparatus for performing heat treatment, or the like.

The one or more container storage apparatuses 120 and 130 may store therein a container. The one or more container storage apparatuses 120 and 130 may temporarily store therein the container. The container may accommodate a plurality of substrates therein. The one or more container storage apparatuses 120 and 130 may store therein a container in which a non-treated substrate is accommodated. The one or more container storage apparatuses 120 and 130 may store therein a container in which a treated substrate is received. For example, the container may be embodied as a front opening unified pod (FOUP). As another example, the substrate may be and/or may include a wafer or a reticle.

The overhead storage apparatus 120 may be installed on a ceiling in the semiconductor manufacturing plant. The overhead storage apparatus 120 may store the container on the ceiling in the semiconductor manufacturing plant. In an embodiment, a plurality of overhead storage apparatuses 120 may be disposed on the ceiling in the semiconductor manufacturing plant. The overhead storage apparatus 120 may include a plurality of shelves. One or more containers may be stored on each shelf. However, the present disclosure is not limited thereto, and the overhead storage apparatus 120 may include a single shelf. For example, the overhead storage apparatus 120 may be embodied as a side track buffer (STB).

The ground-based storage apparatus 130 may be installed on a ground in the semiconductor manufacturing plant. The ground-based storage apparatus 130 may store the container on the ground in the semiconductor manufacturing plant. The ground-based storage apparatus 130 may be provided in a plural manner on the ground in the semiconductor manufacturing plant. However, the present disclosure is not limited thereto and the ground-based storage apparatus 130 may be provided in a single manner. The ground-based storage apparatus 130 may include a plurality of shelves. However, the present disclosure is not limited thereto and the ground-based storage apparatus 130 may include a single shelf. For example, the ground-based storage apparatus 130 may be embodied as a stocker.

The one or more container transport apparatuses 140 and 150 may transport a container. The one or more container transport apparatuses 140 and 150 may transport a container from one substrate treating apparatus of the plurality of substrate treating apparatuses 110 to another substrate treating apparatus thereof. The one or more container transport apparatuses 140 and 150 may transport the container from one substrate treating apparatus to another substrate treating apparatus for subsequent treating on the substrate. For example, the one or more container transport apparatuses 140 and 150 may transport the container from the first substrate treating apparatus 110a to the second substrate treating apparatus 110b. The one or more container transport apparatuses 140 and 150 may transport the container from the plurality of substrate treating apparatuses 110 to the one or more container storage apparatuses 120 and 130 for temporary storage due to a work delay, for example.

The one or more container transport apparatuses 140 and 150 may transport the container from one container storage apparatus to another container storage apparatus. The one or more container transport apparatuses 140 and 150 may transport the container from the overhead storage apparatus 120 to the ground-based storage apparatus 130. The one or more container transport apparatuses 140 and 150 may transport the container from the ground-based storage apparatus 130 to the overhead storage apparatus 120. The one or more container transport apparatuses 140 and 150 may transport the container from one of the plurality of overhead storage apparatuses 120 to another thereof. The one or more container transport apparatuses 140 and 150 may transport the container from one of the plurality of ground-based storage apparatuses 130 to another thereof. The one or more container transport apparatuses 140 and 150 may transport the container from the one or more container storage apparatuses 120 and 130 to one of the plurality of substrate treating apparatuses 110 for subsequent treating of the substrate.

The overhead transport apparatus 140 may move along a rail installed on the ceiling in the semiconductor manufacturing plant. The overhead transport apparatus 140 may carry a single container, or may simultaneously carry the plurality of containers. The overhead transport apparatus 140 may be provided in a plural manner in the semiconductor manufacturing plant, or may be provided in a single manner in the semiconductor manufacturing plant. For example, the overhead transport apparatus 140 may be embodied as an overhead hoist transporter (OHT).

The ground-based transport apparatus 150 may move on the ground in the semiconductor manufacturing plant. The ground-based transport apparatus 150 may be embodied as a robot that may identify a surrounding environment using sensors and/or machine vision and may be autonomously movable without being limited to a predefined fixed path. The ground-based transport apparatus 150 may simultaneously carry the plurality of containers, or may carry a single container at a time. The ground-based transport apparatus 150 may be provided in a plural manner in the semiconductor manufacturing plant, or may be provided in a single manner in the semiconductor manufacturing plant. For example, the ground-based transport apparatus 150 may be embodied as an autonomous mobile robot (AMR), an automated guided vehicle (AGV), or the like.

The ground-based transport apparatus 150 may be associated with the overhead transport apparatus 140 using, for example, a parallel input output (PIO) sensor, and may perform work based on a result of identifying whether the work is possible without redundant work or interference during transport to the facility.

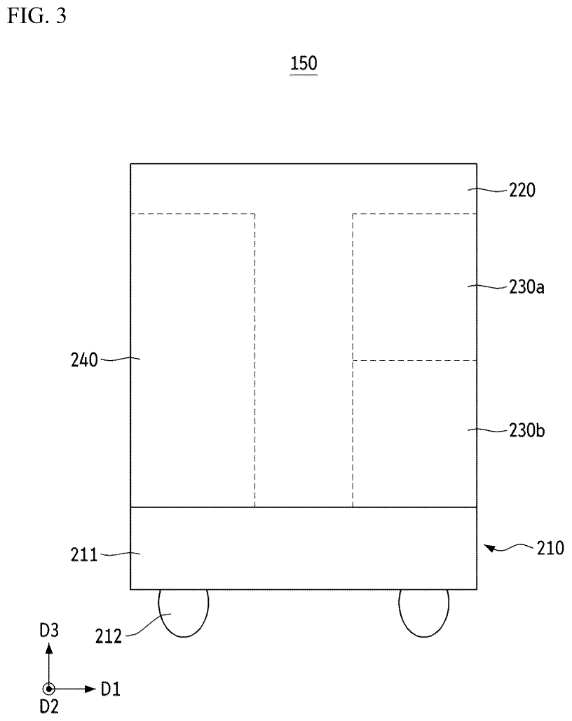

The ground-based transport apparatus 150 may overcome a workspace constraint. For example, the ground-based transport apparatus 150 may move in a narrow space and may carry a container. The ground-based transport apparatus 150 is described with reference to FIGS. 3 to 22.

A control device 160 may control each of the components of the logistics processing system 100. That is, the control device 160 may control an operation of each of the plurality of substrate treating apparatuses 110. The control device 160 may control an operation of each of the container transport apparatuses 140 and 150.

The control device 160 may include a processor for controlling each of the components of the logistics processing system 100, a network interface for performing wired and/or wireless communication with each of the components, a memory storing one or more instructions related to a function and/or operation for controlling each of the components, a memory storing a processing recipe including instructions, various data, or the like. The control device 160 may further include a user interface including an input device (e.g., a keyboard, a mouse, a pointer, or the like) on which an operator may perform a command input manipulation or the like to manage the logistics processing system 100, an output device (e.g., a display, a touchscreen, or the like) for visualizing and/or displaying an operation state of the logistics processing system 100, or the like. The control device 160 may be embodied as a computing device for performing data processing and analysis, command transmission, or the like.

The instructions may be provided in a form of a computer program or an application. The computer program may include one or more instructions and be stored in a computer-readable recording medium. The instructions may include a code generated by a compiler, a code that may be executed by an interpreter, or the like. The memory device may be and/or may include one or more storage media that may include at least one of a flash memory, a hard disk drive (HDD), a solid-state drive (SSD), a card type memory, a random-access memory (RAM), a static RAM (SRAM), a read-only memory (ROM), an electrically erasable programmable ROM (EEPROM), a programmable ROM (PROM), a magnetic memory, a magnetic disk, an optical disk, or the like.

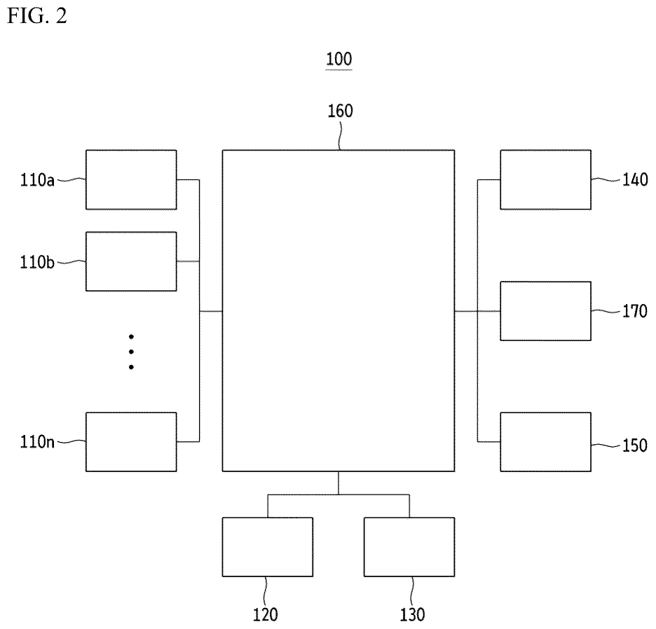

FIG. 2 is a second example diagram for illustrating the concept of the logistics processing system, according to some embodiments of the present disclosure.

Referring to FIG. 2, the one or more container transport apparatuses of the logistics processing system 100 may further include an interlayer transport apparatus 170. The interlayer transport apparatus 170 may interlayer-transport the container within the semiconductor manufacturing plant. The interlayer transport apparatus 170 may transport the container from the ground to the ceiling in the semiconductor manufacturing plant. The interlayer transport apparatus 170 may transport the container from the ceiling to the ground in the semiconductor manufacturing plant. The interlayer transport apparatus 170 may connect the ground and the ceiling to each other in the semiconductor manufacturing plant. The interlayer transport apparatus 170 may carry a single container, or may simultaneously carry a plurality of containers. The interlayer transport apparatus 170 may be provided in a single manner in the semiconductor manufacturing plant, or may be provided in a plural manner in the semiconductor manufacturing plant. For example, the interlayer transport apparatus 170 may be embodied as a lifter.

A related ground-based transport apparatus may transport the container between the one or more container storage apparatuses 120 and 130 in spite of a narrow bay between the apparatuses on the ground. However, the related ground-based transport apparatus may not transport the container between the plurality of substrate treating apparatuses 110 in spite of the narrow bay between the apparatuses on the ground. In this regard, the bay may refer to a space and/or passage defined between facilities necessary for semiconductor manufacturing in the semiconductor manufacturing plant. As such, there is a need to use the ground-based transport apparatus to carry a conveying target object (e.g., the container) between the facilities defining the bay therebetween. However, the related ground-based transport apparatus may not be able to operate because the related ground-based transport apparatus may not be able to enter the bay due to a product size, a rotation radius, or the like. Further, even if the related ground-based transport apparatus may enter the bay, the related ground-based transport apparatus may not be able to operate.

For example, a scheme of using equipment such as, but not limited to, a related mobile robot may be employed. In such an example, a multi-joint robot may be used as a manipulator, and as a result, a relatively wide workspace may be needed for operation thereof, and accordingly, a number of conveying target objects that may be loaded on the robot may be relatively small. Consequently, a transport efficiency of the related mobile robot may be relatively low. Further, a total size of the related mobile robot may be relatively large and thus, it may be difficult to apply the related mobile robot to a narrow bay. That is, the related mobile robot may need to be designed to have a minimum size in consideration of a movement in a narrow space and traffic between multiple mobile robots, as well as, the related mobile robot may need to be designed to load a relatively large number of conveying target objects thereon.

In order to address the above problems and to cope with the above situations, the ground-based transport apparatus 150, according to the present disclosure, may directly transport the conveying target object from and/or to the facility, and at the same time, may be designed to have a minimum size so as to drive in a small space. Hereinafter, the ground-based transport apparatus 150, according to the present disclosure is described.

The ground-based transport apparatus 150 may be embodied as a mobile robot that may be configured to directly transport the conveying target object (or an article) from and/or to the facility for manufacturing the semiconductor device. The ground-based transport apparatus 150 may be equipped with a manipulator including a selective compliance assembly robot arm (SCARA), and may load and/or unload the conveying target object (e.g., the container) using the manipulator. Furthermore, the ground-based transport apparatus 150 may be configured to perform autonomous driving on the ground to transport the conveying target object to and/or from each of various facilities such as, but not limited to, the article storage facilities and semiconductor manufacturing facilities. The ground-based transport apparatus 150 may load and/or unload a conveying target object on and/or out of the article storage facility, that is, a manual port of the ground-based storage apparatus 130. Furthermore, the ground-based transport apparatus 150 may load and/or unload the conveying target object on and/or out of an equipment front end module (EFEM) of the semiconductor manufacturing facility (e.g., each of the plurality of substrate treating apparatuses 110. The ground-based transport apparatus 150 may include, but not be limited to, precision positioning and/or docking functions, a facility interface function, a multiple loading structure of the conveying target object, robot arms, or the like.

FIG. 3 is a first example diagram for illustrating a structure of the ground-based transport apparatus 150 of the logistics processing system 100, according to some embodiments of the present disclosure. Referring to FIG. 3, the ground-based transport apparatus 150 may be configured to include a driving module 210, a housing 220, a shelf structure including a first shelf module 230a, a second shelf module 230b, and a manipulator module 240.

A first direction D1 and a second direction D2 may constitute a two-dimensional plane. The first direction D1 may be an X-axis direction, and the second direction D2 may be a Y-axis direction. The first direction D1 may be a left-right direction, and the second direction D2 may be a front-rear direction. However, the present disclosure is not limited in this regard. For example, the first direction D1 may be a front-rear direction, and the second direction D2 may be a left-right direction. A third direction D3 together with the first direction D1 and the second direction D2 may constitute a three-dimensional solid. The third direction D3 may be a direction perpendicular to the plane defined by the first direction D1 and the second direction D2. The third direction D3 may be a Z-axis direction. The third direction D3 may be a vertical direction.

The driving module 210 may perform autonomous driving, power charging, and power supply functions of the ground-based transport apparatus 150. For example, the driving module 210 may include hardware and/or software components for providing the autonomous driving, power charging, and power supply functions to the ground-based apparatus 150. In an embodiment, the driving module 210 may include, but not be limited to, motors, brakes, sensors (e.g., incline sensors, speed sensors, accelerometers, distance sensors, or the like), actuators, charging circuits, batteries, transformers, or the like for providing the autonomous driving, power charging, and power supply functions to the ground-based apparatus 150. In an embodiment, the driving module 210 may be physically implemented by analog and/or digital circuits including one or more of a logic gate, an integrated circuit, a microprocessor, a microcontroller, a memory circuit, a passive electronic component, an active electronic component, an optical component, and the like. For example, a field programmable gate array (FPGA) may be used to implement custom logic that may include the functionality of the driving module 210. As another example, one or more processors in combination with a memory may be used to execute, individually or collectively, one or more instructions to perform at least a portion of the functionality of the driving module 210 and/or the ground-based transport apparatus 150. Alternatively or additionally, at least a portion of the functionality of driving module 210 may be incorporated into the control device 160 and/or implemented as instructions to be executed by the control device 160. In an embodiment, the driving module 210 may be referred to as a driving controller.

When the autonomous driving function is performed by the driving module 210, the driving module 210 may recognize (identify) a geographical feature using one or more sensors such as, but not limited to, light detection and ranging (LiDAR) sensors, laser distance sensors (LDS), or the like, and may search for an optimal route when moving based on the recognized geographical feature, and thus may perform autonomous driving between the facilities.

When the ground-based transport apparatus 150 docks to the EFEM of each of the plurality of substrate treating apparatuses 110 and/or the manual port of the ground-based storage apparatus 130 for the loading and unloading work, the driving module 210 may recognize and/or may correct a relative position between the ground-based transport apparatus 150 and the facility (EFEM or the manual port) using a quick response (QR) reader, thereby implementing precise positioning thereof. However, the present disclosure is not limited in this regard, and the ground-based transport apparatus 150 may implement precise positioning in various other manners without departing from the scope of the present disclosure.

In an embodiment, the driving module 210 may include a wireless charging system. A receive (RX) module may be installed in the driving module 210, and a transfer (TX) module may be installed in the facility, so that the RX module of the ground-based transport apparatus 150 may wirelessly receive power from the TX module to charge a built-in battery during the loading and/or unloading work. Accordingly, the ground-based transport apparatus 150 may operate for a relatively long time (e.g., 24 hours) without having a separate charging time during which loading and/or unloading work may be paused.

The driving module 210 may include a first body 211 and a plurality of wheels 212. The plurality of wheels 212 may be installed on a bottom surface of the first body 211. The ground-based transport apparatus 150 may perform autonomous driving on the ground in the semiconductor manufacturing plant using the plurality of wheels 212.

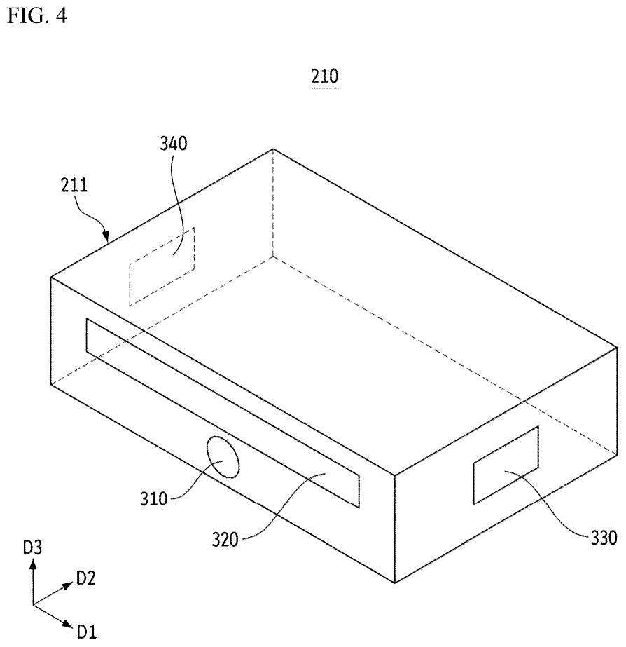

FIG. 4 is a first example diagram for illustrating a driving module 210 of the ground-based transport apparatus 150, according to some embodiments of the present disclosure. Referring to FIG. 4, the first body 211 may include a code reader 310, a charging pad 320, a first image measurement sensor 330, and a second image measurement sensor 340. For convenience of illustration, the plurality of wheels 212 wheels may be omitted in FIG. 4. However, it may be apparent that the plurality of wheels 212 may be installed on the bottom surface of the first body 211 as described with reference to FIG. 3.

The code reader 310 may read a code attached to the EFEM of each of the plurality of substrate treating apparatuses 110 and/or the manual port of the ground-based storage apparatus 130. The code may store therein information about a corresponding facility. The control device 160 may determine whether the corresponding facility is a destination based on the code read by the code reader 310. The code attached to the EFEM and/or the manual port may be a QR code or a barcode. However, the code is not limited thereto in the present disclosure.

The charging pad 320 may receive power from the EFEM and/or the manual port. For example, the charging pad 320 may include the RX module, and each of the EFEM and the manual port may include the TX module. The RX module of the charging pad 320 may receive the power from the TX module to charge a battery installed in the ground-based transport apparatus 150. The charging pad 320 may be embodied as a wireless charging pad that wirelessly charges the power. However, the present disclosure is not limited thereto, and for example, the charging pad may be embodied as a contact type charging pad.

In an embodiment, the charging pad 320 may charge power while the ground-based transport apparatus 150 loads the container into each of the plurality of substrate treating apparatuses 110. Alternatively or additionally, the charging pad 320 may charge the power while the ground-based transport apparatus 150 unloads the container from each of the plurality of substrate treating apparatuses 110. In an embodiment, the charging pad 320 may charge the power while the ground-based transport apparatus 150 loads the container onto the ground-based storage apparatus 130. As another example, the charging pad 320 may charge the power while the ground-based transport apparatus 150 unloads the container from the ground-based storage apparatus 130.

As shown in FIG. 4, the code reader 310 and the charging pad 320 may not be covered with a surface of the first body 211 so as to be exposed to an outside. The code reader 310 and the charging pad 320 may be installed on the same surface of the first body 211, or may be installed on different surfaces thereof, respectively.

The first image measurement sensor 330 and the second image measurement sensor 340 may acquire a surrounding image around the ground-based transport apparatus 150. The first image measurement sensor 330 and the second image measurement sensor 340 may acquire the surrounding image using different schemes. For example, the first image measurement sensor 330 may be embodied as a camera sensor, and the second image measurement sensor 340 may be embodied as a LiDAR sensor. However, the present disclosure is not limited thereto, and the first image measurement sensor 330 and the second image measurement sensor 340 may acquire the surrounding image using a same scheme and/or a different scheme.

The first image measurement sensor 330 and the second image measurement sensor 340 may not be covered with the surface of the first body 211 so as to be exposed to the outside. The first image measurement sensor 330 and the second image measurement sensor 340 may be respectively installed on different surfaces of the first body 211 and respectively acquire different images around the ground-based transport apparatus 150 in different directions. However, the present disclosure is not limited thereto. For example, at least one of the first image measurement sensor 330 and the second image measurement sensor 340, and the code reader 310 and the charging pad 320 may be installed on the same surface of the first body 211.

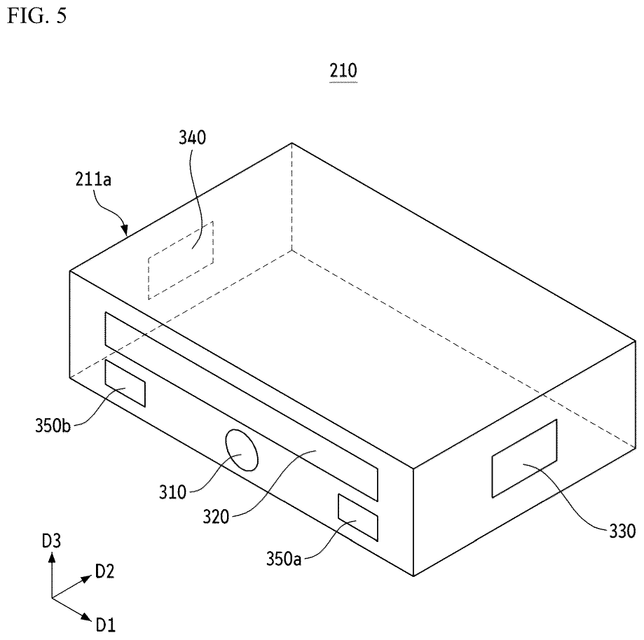

FIG. 5 is a second example diagram for illustrating a driving module 210 of the ground-based transport apparatus 150, according to some embodiments of the present disclosure. A first body 211a may include and/or may be similar in many respects to the first body 211 described above with reference to FIGS. 3 and 4, and may include additional features not mentioned above. Consequently, repeated descriptions of the first body 211a described above with reference to FIGS. 3 and 4 may be omitted for the sake of brevity. For convenience of illustration, the plurality of wheels 212 wheels may be omitted in FIG. 5. However, it may be apparent that the plurality of wheels 212 may be installed on the bottom surface of the first body 211a as described with reference to FIG. 3.

Referring to FIG. 5, the first body 211a may further include a first distance measuring sensor 350a and a second distance measuring sensor 350b.

Each of the first distance measuring sensor 350a and the second distance measuring sensor 350b may measure a distance between the ground-based transport apparatus 150 and the EFEM. Each of the first distance measuring sensor 350a and the second distance measuring sensor 350b may measure the distance between the EFEM 150 and the ground-based transport apparatus when the code reader 310 reads the code attached to the EFEM. Each of the first distance measuring sensor 350a and the second distance measuring sensor 350b may measure the distance between the ground-based transport apparatus 150 and the manual port. Each of the first distance measuring sensor 350a and the second distance measuring sensor 350b may measure the distance between the ground-based transport apparatus 150 and the manual port when the code reader 310 reads the code attached to the manual port. The first distance measuring sensor 350a and the second distance measuring sensor 350b may measure the distance between the ground-based transport apparatus 150 and the facility using a substantially similar and/or the same scheme. For example, each of the first distance measuring sensor 350a and the second distance measuring sensor 350b may be embodied as a laser distance sensor (LDS).

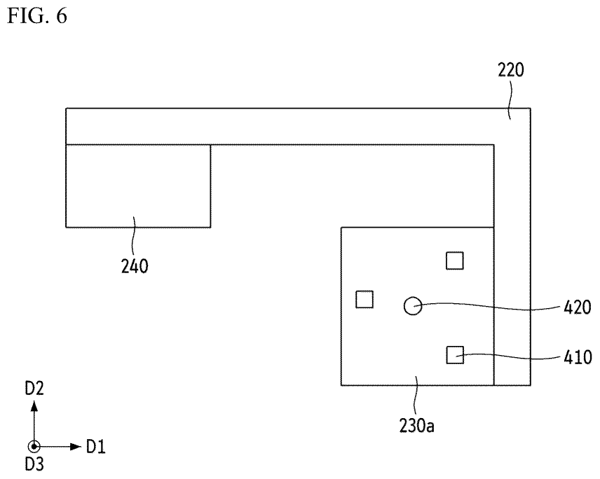

FIG. 6 is a first example diagram for illustrating the housing and the shelf module of the ground-based transport apparatus, according to some embodiments of the present disclosure.

Referring to FIGS. 3 and 6 together, the housing 220 may be disposed on the driving module 210. The first and second shelf modules 230a and 230b and the manipulator module 240 may be disposed in the housing 220. As shown in FIG. 6, all sides of the housing 220 may not be closed. For example, two (2) sides of the housing 220 may be closed and the other two (2) sides thereof may be opened. However, the present disclosure is not limited thereto, and three (3) sides of the housing 220 may be closed and one (1) side thereof may be opened. In such an example, the manipulator module 240 may input and withdraw the container through the open side.

The first and second shelf modules 230a and 230b may be supported by the housing 220. The first and second shelf modules 230a and 230b may be and/or may include a plurality of shelves received in the housing 220. For example, the first and second shelf modules 230a and 230b may include the first shelf 230a and the second shelf 230b. The first shelf 230a and the second shelf 230b may be arranged in the third direction D3. The first shelf 230a may be stacked on top of the second shelf 230b. However, the present disclosure is not limited thereto, and the first shelf 230a and the second shelf 230b may be arranged in the first direction D1 or the second direction D2. For example, the first shelf 230a and the second shelf 230b may be arranged side by side in the horizontal direction.

The first and second shelf modules 230a and 230b may include a plurality of layers arranged vertically to simultaneously load a plurality of conveying target objects thereon, and the manipulator module 240 may be installed in a space adjacent thereto. The ground-based transport apparatus 150 may be designed to have the above structure to provide a relatively high transport efficiency within a relatively limited size, when compared to related mobile robots.

The first and second shelf modules 230a and 230b may include various types of sensors. The first and second shelf modules 230a and 230b may include a sensor that may detect whether the conveying target object is loaded thereon. The first and second shelf modules 230a and 230b may include a sensor that may detect whether the conveying target object is in a correct position. The first and second shelf modules 230a and 230b may include a sensor for detecting whether a cover of the container is opened.

Referring to FIG. 6, a pin assembly 410 and a sensor 420 may be disposed on an upper surface of the first shelf 230a. The sensor 420 may be a sensor that may detect whether the container is loaded. Alternatively or additionally, the sensor 420 may be a sensor that may detect whether the container is in the correct position. Although FIG. 6 shows that the sensor 420 is provided in a single manner, a plurality of sensors 420 may be provided. For example, the plurality of sensors 420 may include a sensor for detecting whether the container has been loaded and a sensor for detecting whether the container is in the correct position. In an embodiment, the sensor 420 may be and/or may include, but not be limited to, an optical sensor.

The pin assembly 410 may fix the container when the container has been seated on the first shelf 230a. A plurality of pin assemblies 410 may be disposed on the first shelf 230a to minimize shaking of the container. However, the present disclosure is not limited thereto, and the container may be fixed to the first shelf 230a using various other implementations. The pin assembly 410 may be provided in a single manner or may be provided in a plural manner.

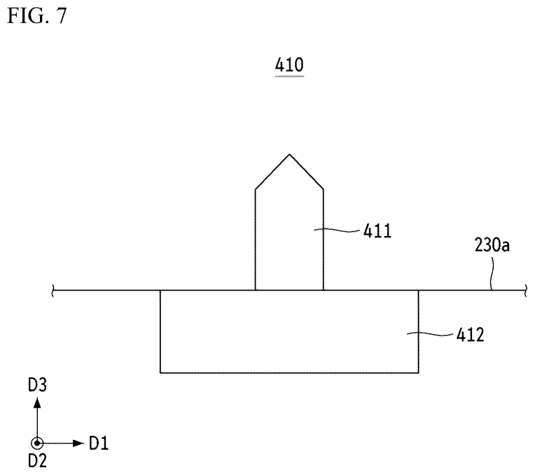

FIG. 7 is a second example diagram for illustrating the housing 220 and the shelf module 230a of the ground-based transport apparatus 150, according to some embodiments of the present disclosure. Referring to FIG. 7, the pin assembly 410 may include a fixing pin 411 and an anti-vibration structure 412. The fixing pin 411 may fix the container. For example, the fixing pin 411 may be and/or may include, but not be limited to, a kinematic pin. The anti-vibration structure 412 may be installed under the fixing pin 411. The fixing pin 411 may be exposed to the outside upwardly of the first shelf 230a, and the anti-vibration structure 412 may not be exposed to the outside while being disposed on the first shelf 230a. The anti-vibration structure 412 may be made of a polymer. The anti-vibration structure 412 may minimize (reduce) transmission of vibration generated while the ground-based transport apparatus 150 is driving to the container. For example, the anti-vibration structure 412 may be and/or may include a damper.

The second shelf 230b may provide a seating surface on which the container is seated, and may support the container when the container is seated thereon. For example, the configuration of the second shelf 230b may be similar in many respects to the configuration of the first shelf 230a described above with reference to FIGS. 6 and 7, and may include additional features not mentioned above. Furthermore, the pin assembly 410 and the sensor 420 may be equally applied to the second shelf 230b. Consequently, repeated descriptions of the second shelf 230b described above with reference to FIGS. 6 and 7 may be omitted for the sake of brevity.

In an embodiment, the code reader 310, the first image measurement sensor 330, and the second image measurement sensor 340 may be disposed on the housing 220. In such an example, the code reader 310, the first image measurement sensor 330, and the second image measurement sensor 340 may not be disposed on the driving module 210. Alternatively, the code reader 310, the first image measurement sensor 330, and the second image measurement sensor 340 may be disposed on both the driving module 210 and the housing 220.

In an embodiment, a power switch, a reset switch, a touch panel, a brake release switch, a black box, or the like may be further disposed on the housing 220. The power switch may cause the ground-based transport apparatus 150 to start operating. The reset switch may reset the operation of the ground-based transport apparatus 150 when an error occurs in the operation of the ground-based transport apparatus 150. The touch panel may perform an information input and output function. The brake release switch may relieve braking of the ground-based transport apparatus 150. The black box may store therein images and/or sounds around the ground-based transport apparatus 150 while the ground-based transport apparatus 150 is operating. Alternatively or additionally, the black box may further store telemetry and/or diagnostic data that may be used to analyze the operation of the ground-based transport apparatus 150, during a fault operation, for example.

In an embodiment, a status indicator, a communication module, a vision sensor, an ultrasonic sensor, or the like may be further disposed on the housing 220. The status indicator may indicate the status of the ground-based transport apparatus 150. The communication module may be used to communicate with another ground-based transport apparatus 150, the overhead transport apparatus 140, the control device 160, or the like. For example, the communication module may include, but not be limited to, a wireless local area network (WLAN) module, a PIO sensor, or the like. The vision sensor may be associated with the black box. The ultrasonic sensor may detect whether the cover of the container is opened, for example.

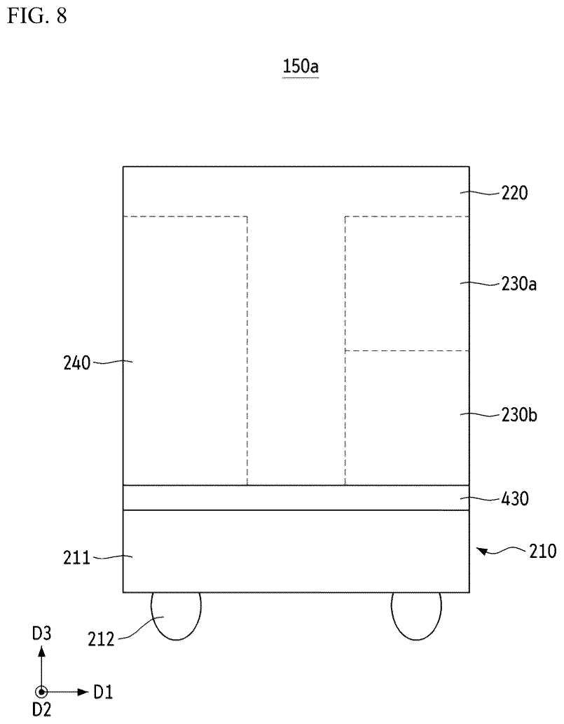

FIG. 8 is a second example diagram for illustrating a structure of the ground-based transport apparatus of the logistics processing system 100, according to some embodiments of the present disclosure. Referring to FIG. 8, a ground-based transport apparatus 150a may include and/or may be similar in many respects to the ground-based transport apparatus 150 described above with reference to FIGS. 1 to 7, and may include additional features not mentioned above. Consequently, repeated descriptions of the ground-based transport apparatus 150a described above with reference to FIGS. 1 to 7 may be omitted for the sake of brevity.

In an embodiment, the ground-based transport apparatus 150a may further include an elastic structure 430. The elastic structure 430 may be installed between the driving module 210 and the housing 220. However, the present disclosure is not limited thereto, and the elastic structure 430 may be installed on an outer surface of the housing 220. The elastic structure 430 may absorb an impact when the ground-based transport apparatus 150 collides with another apparatus or facility. The elastic structure 430 may minimize the impact being transmitted to the container. For example, the elastic structure 430 may be and/or may include a bumper.

Returning to FIG. 3, the first and second shelf modules 230a and 230b and the manipulator module 240 may be disposed in an inner space of the housing 220. The manipulator module 240 may be disposed in the housing 220 so as to be spaced apart from the first and second shelf modules 230a and 230b.

The manipulator module 240 may include the SCARA for plane motion and a linear actuator for vertical motion. However, the present disclosure is not limited, and the manipulator module 240 may include various other devices and/or assemblies to implement the functions of the manipulator module 240 described herein, without departing from the scope of the present disclosure. As used herein, the manipulator module 240 may be referred to as a manipulator arm assembly. The manipulator module 240 may perform a combination of the plane and/or vertical motions to access the first and second shelf modules 230a and 230b. Furthermore, the manipulator module 240 may perform a combination of the plane and/or vertical motions to access the EFEM and/or the manual port.

The SCARA may include a plurality of assemblies, such as, but not limited to, a base assembly, a first arm assembly, a second arm assembly, and a hand assembly. The base assembly may connect the SCARA to a linear actuator. The first arm assembly and the second arm assembly may implement the plane motion. The hand assembly may perform the conveying of the target object. The hand assembly may include, but not be limited to, a gripper, a photo sensor, or the like, for performing the conveying of the target object. The gripper may include elements such as, but not limited to, a motor, a linear motion (LM) guide, a ball screw, or the like. In an embodiment, the hand assembly may include a plurality of photo sensors. At least one photo sensor of the plurality of photo sensors may capture an image and/or may recognize (identify) a flange of the container based on the captured image. The gripper may be associated with the photo sensor and may be configured to grip the container when the flange of the container is recognized by the photo sensor.

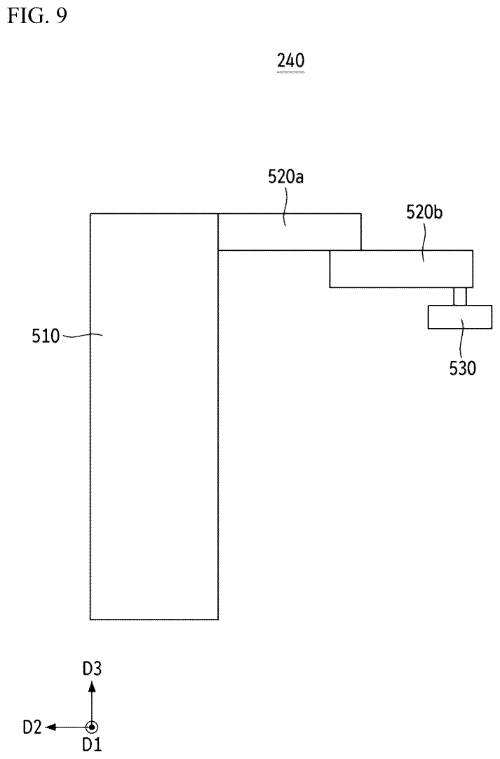

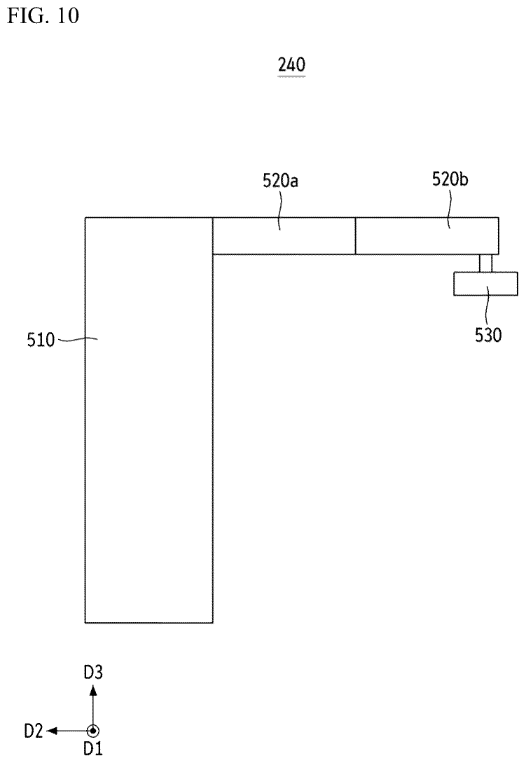

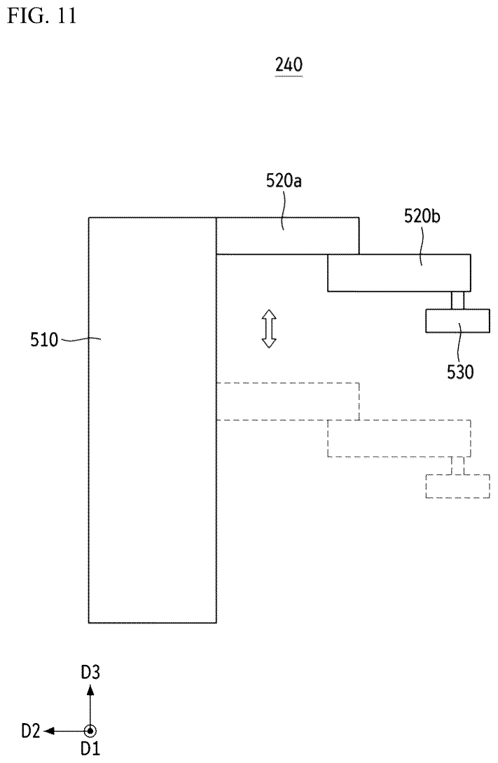

FIG. 9 is a first example diagram for illustrating a manipulator module of the ground-based transport apparatus 150, according to some embodiments of the present disclosure. FIG. 10 is a second example diagram for illustrating a manipulator module of the ground-based transport apparatus 150, according to some embodiments of the present disclosure. FIG. 11 is a third example diagram for illustrating a manipulator module of the ground-based transport apparatus 150, according to some embodiments of the present disclosure. Referring to FIGS. 9 to 11, the manipulator module 240 may include a second body 510, a first arm 520a, a second arm 520b, and a hand 530.

The first arm 520a may be coupled to the second body 510. The first arm 520a may rotate clockwise. Alternatively or additionally, the first arm 520a may rotate counterclockwise. The first arm 520a may rotate in the first direction D1 and the second direction D2. The first arm 520a may include a base assembly and a first arm assembly.

The second arm 520b may be coupled to the first arm 520a. The second arm 520b may rotate clockwise. Alternatively or additionally, the second arm 520b may rotate counterclockwise. The second arm 520b may rotate in the first direction D1 and the second direction D2. The second arm 520b may include a first arm assembly.

Referring to FIG. 9, the second arm 520b may be located at a different level from a level of the first arm 520a. The second arm 520b may be located at a lower level than that of the first arm 520a. However, the present disclosure is not limited thereto. For example, as shown in FIG. 10, the second arm 520b may be positioned at the same level as that of the first arm 520a. The first arm 520a and the second arm 520b may rotate in the same direction. The first arm 520a and the second arm 520b may rotate in different directions. The first arm 520a and the second arm 520b may operate independently.

The hand 530 may be coupled to an end of the second arm 520b. Although the hand 530 is shown as being coupled to a bottom surface of the end of the second arm 520b in FIGS. 9 to 11, the present disclosure is not limited in this regard, and for example, the hand 530 may be coupled to an upper surface or a side surface of the end of the second arm 520b. The hand 530 may grip the container. The hand 530 may be and/or may include, but not be limited to, an end effector. The hand 530 may include the hand assembly.

Referring to FIG. 11, the first arm 520a, the second arm 520b, and the hand 530 may move in the third direction D3. The first arm 520a, the second arm 520b, and the hand 530 may move in the third direction D3 in a state of being coupled to the second body 510. The second body 510 may include a linear actuator. The second body 510 may move the first arm 520a, the second arm 520b, and the hand 530 in the third direction D3.

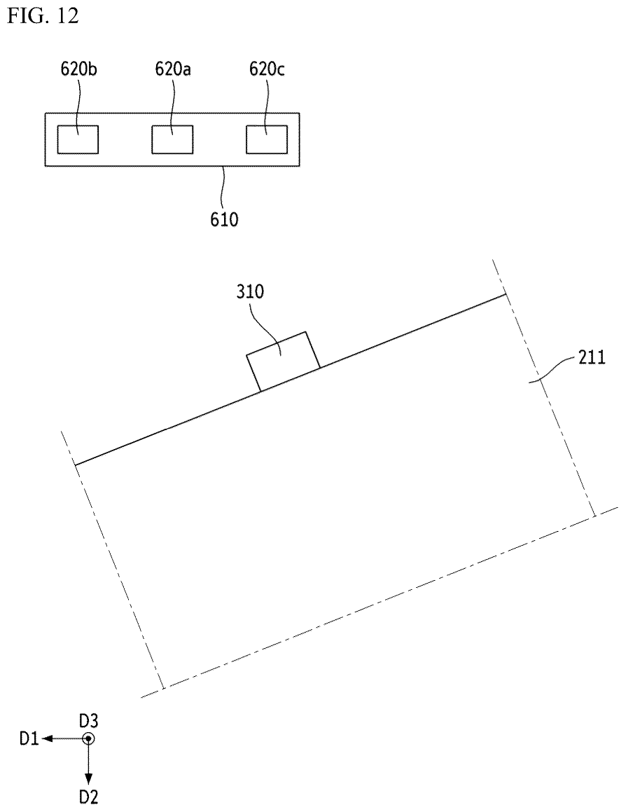

Hereinafter, a docking sequence of the ground-based transport apparatus 150 is described with reference to FIG. 12. FIG. 12 is a first example diagram for illustrating a docking sequence of a ground-based transport apparatus 150, according to some embodiments of the present disclosure.

The ground-based transport apparatus 150 may access each of the plurality of substrate treating apparatuses 110 to remove the container from each of the plurality of substrate treating apparatuses 110 or to input the container into each of the plurality of substrate treating apparatuses 110. The ground-based transport apparatus 150 may access the EFEM of each of the plurality of substrate treating apparatuses 110. An identification code may be attached to the EFEM.

The identification code may be and/or may include a vertical code and may be attached to the EFEM. Alternatively or additionally, the identification code may be and/or may include a horizontal code and may be attached to the EFEM. The vertical code may refer to a code that may be attached to an upper surface of a plate. When a plate 610 constitutes a side surface of the EFEM, a plurality of identification codes (e.g., a first identification code 620a, a second identification code 620b, and a third identification code 620c, hereinafter generally referred to as “620”) may be formed on the upper surface of the plate 610. When the plurality of identification codes 620 is the vertical code, a plurality of vertical identification codes may be provided. For example, three (3) identification codes (e.g., first to third identification codes 620a to 620c) may be provided. Hereinafter, the docking sequence when the identification code is the vertical code is described with reference to FIGS. 12 to 15.

When a posture of the ground-based transport apparatus 150 is not correct, the ground-based transport apparatus 150 may not be able to bring the container into the EFEM and/or take the container out of the EFEM. Accordingly, it may be necessary to correct the posture of the ground-based transport apparatus 150 facing EFEM before bringing in the container and/or taking out the container. X-axis coordinate information, y-axis coordinate information, and θ-axis coordinate information may be needed to correct the posture of the ground-based transport apparatus 150.

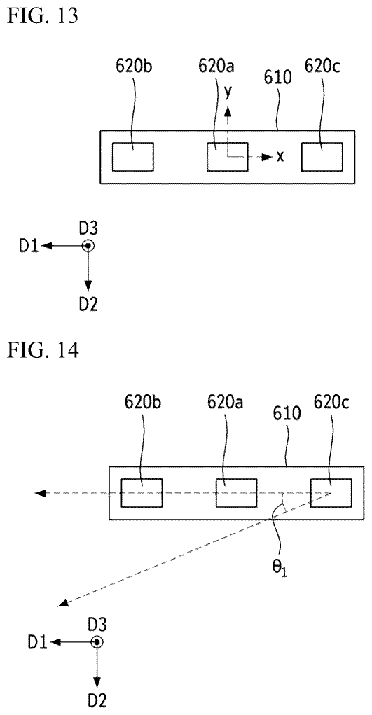

FIG. 13 is a second example diagram for illustrating a docking sequence of the ground-based transport apparatus 150, according to some embodiments of the present disclosure. Referring to FIG. 13, the ground-based transport apparatus 150 may use the x-axis coordinate of the first identification code 620a as the x-axis coordinate information. In addition, the ground-based transport apparatus 150 may use the y-axis coordinate of the first identification code 620a as the y-axis coordinate information. The ground-based transport apparatus 150 may receive the x-axis coordinate and the y-axis coordinate of the first identification code 620a from the control device 160, and/or may directly measure the x-axis coordinate and the y-axis coordinate of the first identification code 620a using a sensor.

FIG. 14 is a third example diagram for illustrating a docking sequence of the ground-based transport apparatus, according to some embodiments of the present disclosure. Referring to FIG. 14, the second identification code 620b and the third identification code 620c may be respectively disposed on both opposing sides of the first identification code 620a. When a line segment connecting the second identification code 620b and the third identification code 620c to each other is defined as a first line segment and a line segment in a direction parallel to a front surface of the driving module 210 is defined as a second line segment, a first angle θ₁ defined between the first line segment and the second line segment may be measured. The ground-based transport apparatus 150 may use the first angle θ₁ as the θ-axis coordinate information.

For example, when there are three (3) or more identification codes, a line segment connecting the two (2) outermost codes may be defined as the first line segment. When the identification code is a vertical code, the first distance measuring sensor 350a and the second distance measuring sensor 350b may not be used in the docking sequence. The substrate transport apparatus 150 may not include the first distance measuring sensor 350a and the second distance measuring sensor 350b.

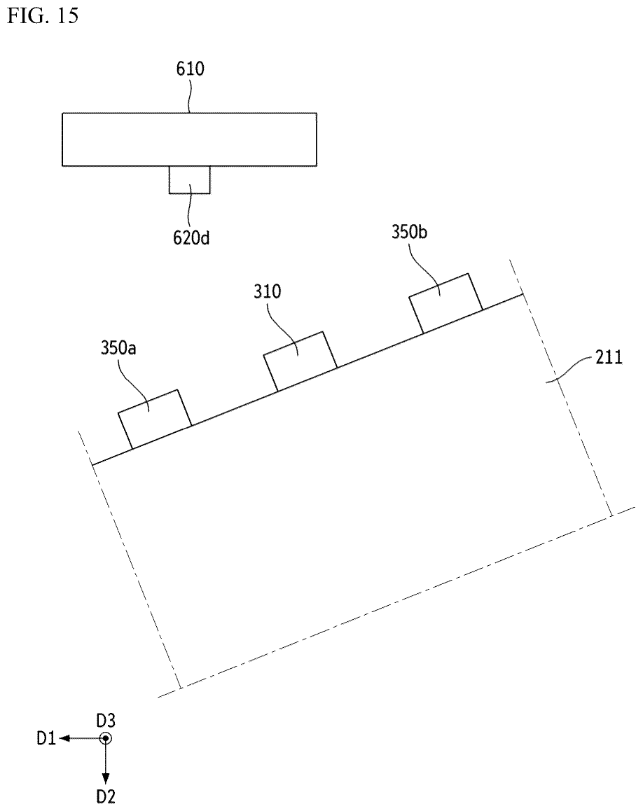

FIG. 15 is a fourth example diagram for illustrating a docking sequence of the ground-based transport apparatus, according to some embodiments of the present disclosure. Referring to FIG. 15, the horizontal code may refer to a code attached to a side surface of the plate. When the side surface of the EFEM comprises the plate 610, a fourth identification code 620d may be formed on the side surface of the plate 610. When the fourth identification code 620d is a horizontal code, the fourth identification code 620d may be provided as a single code. Hereinafter, the docking sequence when the identification code is the horizontal code is described with reference to FIGS. 15 to 17.

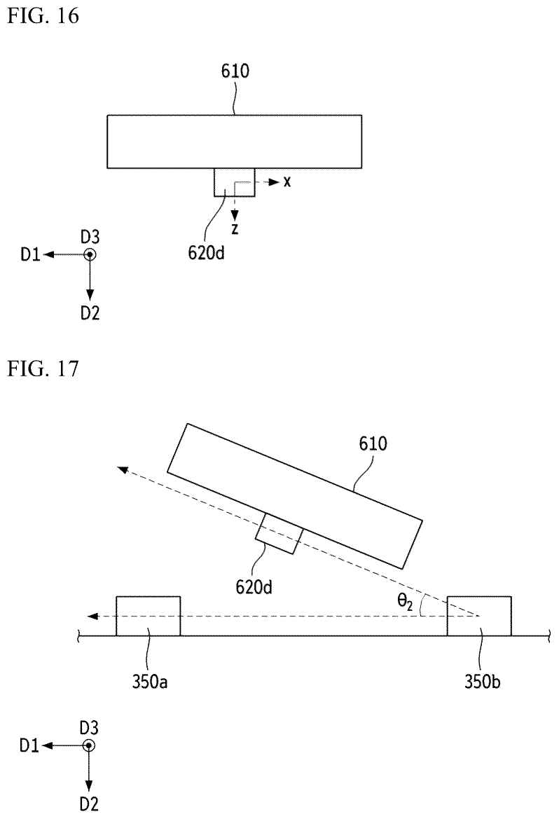

FIG. 16 is a fifth example diagram for illustrating a docking sequence of the ground-based transport apparatus 150, according to some embodiments of the present disclosure. Referring to FIG. 16, the ground-based transport apparatus 150 may use the x-axis coordinate of the fourth identification code 620d as the x-axis coordinate information. Furthermore, the ground-based transport apparatus 150 may use the y-axis coordinate of the fourth identification code 620d as the z-axis coordinate information. The ground-based transport apparatus 150 may receive the x-axis coordinate and the z-axis coordinate of the fourth identification code 620d from the control device 160, and/or may directly measure the x-axis coordinate and the z-axis coordinate of the fourth identification code 620d using a sensor.

The ground-based transport apparatus 150 may generate y-axis coordinate information using the first distance measuring sensor 350a and the second distance measuring sensor 350b. For example, the ground-based transport apparatus 150 may generate the y-axis coordinate information based on an average value of a measured value of the first distance measuring sensor 350a and a measured value of the second distance measuring sensor 350b.

FIG. 17 is a sixth example diagram for illustrating a docking sequence of the ground-based transport apparatus 150, according to some embodiments of the present disclosure. Referring to FIG. 17, the first distance measuring sensor 350a and the second distance measuring sensor 350b may be disposed on the front surface of the driving module 210. When a line segment connecting the first distance measuring sensor 350a and the second distance measuring sensor 350b is defined as a third line segment and a line segment in a direction parallel to a front surface of the plate 610 is defined as a fourth line segment, a second angle θ₂ defined between the third line segment and the fourth line segment may be measured. The ground-based transport apparatus 150 may use the second angle θ₂ as the θ-axis coordinate information.

For example, a code reader coordinate system that may be applied when the identification code is the horizontal code may be different from a code reader coordinate system that may be applied when the identification code is the vertical code.

The ground-based transport apparatus 150 may access the ground-based storage apparatus 130 to input the container into the ground-based storage apparatus 130 and/or to remove containers from the ground-based storage apparatus 130. The ground-based transport apparatus 150 may access the manual port of the ground-based storage apparatus 130. An identification code may be attached to the manual port. The identification code may be embodied as the vertical code or the horizontal code and may be attached to the manual port. The docking sequence when a docking target is the manual port may be substantially similar and/or the same as the docking sequence when the docking target is the EFEM. Accordingly, a repeated description thereof may be omitted for the sake of brevity.

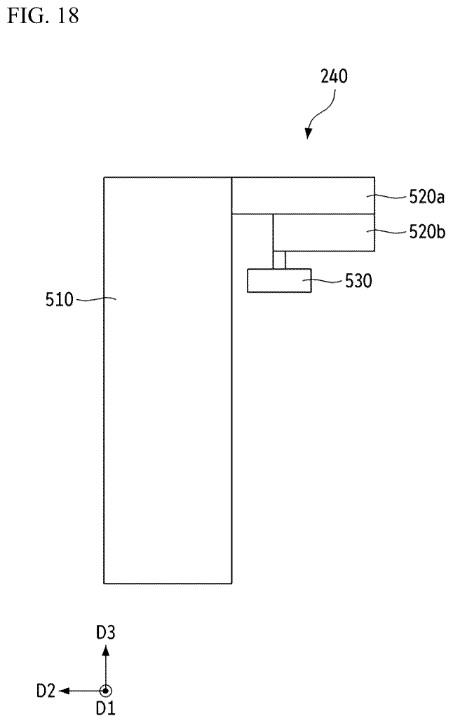

Hereinafter, a handling sequence of the ground-based transport apparatus 150 is described with reference to FIGS. 18 to 22.

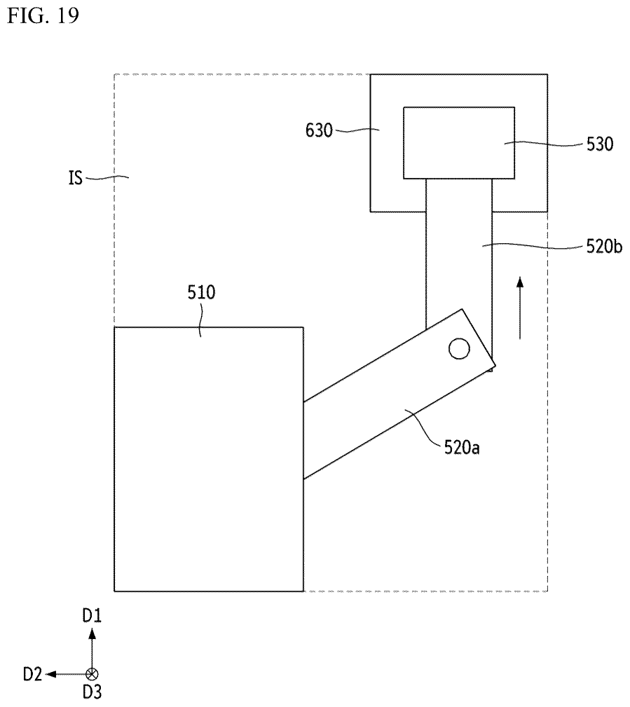

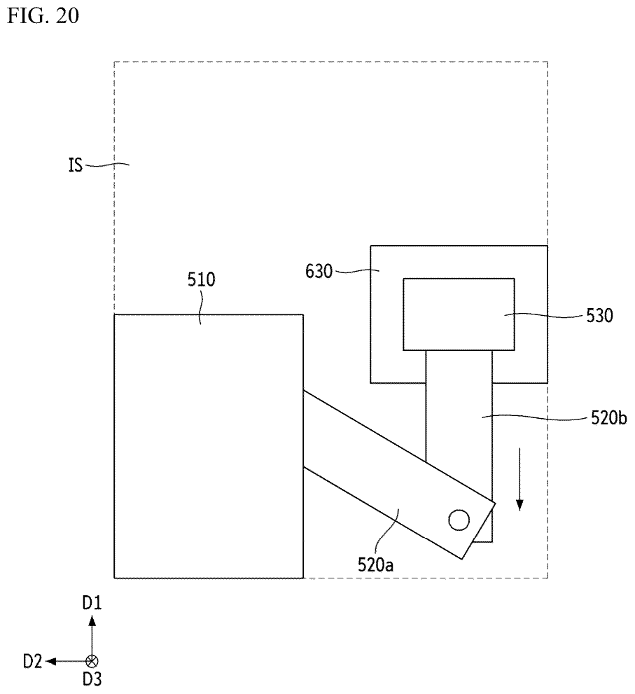

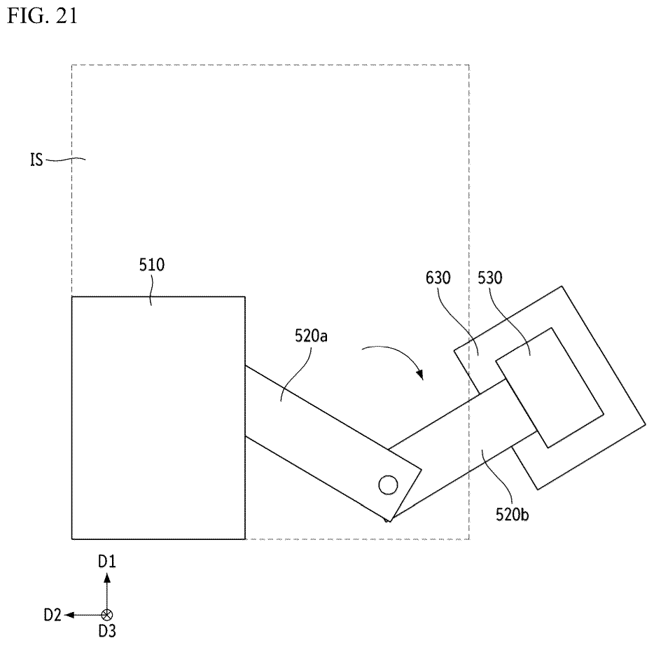

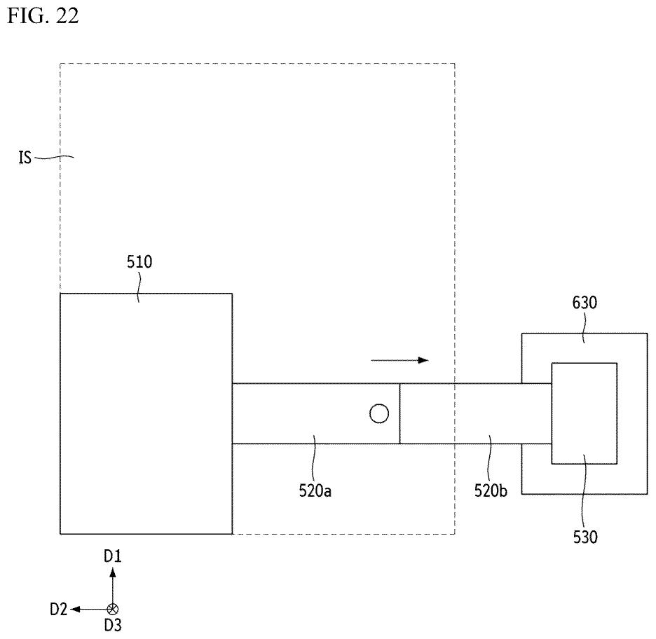

FIG. 18 is a first example diagram for illustrating a handling sequence of a ground-based transport apparatus 150, according to some embodiments of the present disclosure. FIG. 19 is a second example diagram for illustrating a handling sequence of the ground-based transport apparatus, according to some embodiments of the present disclosure. FIG. 20 is a third example diagram for illustrating a handling sequence of the ground-based transport apparatus, according to some embodiments of the present disclosure. FIG. 21 is a fourth example diagram for illustrating a handling sequence of a ground-based transport apparatus, according to some embodiments of the present disclosure. FIG. 22 is a fifth example diagram for illustrating a handling sequence of the ground-based transport apparatus, according to some embodiments of the present disclosure. Hereinafter, an example in which the ground-based transport apparatus 150 takes out the container to the EFEM and/or the manual port is taken out is described.

Referring to FIGS. 18 and 19 together, the ground-based transport apparatus 150 may have a reduced size compared to that of a related apparatus so as to move in a narrow space on the ground. Accordingly, an inner space IS of the housing 220 may be relatively narrow. Typically, the first arm 520a, the second arm 520b, and the hand 530 may be disposed over each other in consideration of the narrow inner space IS. For example, the second arm 520b may entirely and/or partially overlap the first arm 520a.

As shown in FIG. 19, the first arm 520a and the second arm 520b may perform a joint motion to position the hand 530 on top of the container 630. The hand 530 may grip the container 630. When a vertical level of the hand 530 is different from a vertical level of the container 630, the linear actuator in the second body 510 may adjust the vertical levels of the first arm 520a, the second arm 520b, and the hand 530.

Subsequently, referring to FIG. 20, the first arm 520a and the second arm 520b may perform a retract motion. Due to the retract movement of the first arm 520a and the second arm 520b, the container 630 may move out of the seating surface of the first and second shelf modules 230a and 230b and then to a position in front of the front surface of the second body 510.

Subsequently, referring to FIG. 21, the second arm 520b may pivot clockwise. For example, the first arm 520a may maintain a current position without moving, and/or may move slightly in the opposite direction to the first direction. The container 630 may move further forwards beyond a previous position as the second arm 520b pivots.

As shown in FIG. 22, the first arm 520a and the second arm 520b may extend to allow the container 630 to reach the EFEM or manual port. The first arm 520a and the second arm 520b may be unfolded relative to each other so that the longitudinal directions thereof may be in the same line. The container 630 may be transferred to the EFEM and/or the manual port in a state in which the first arm 520a and the second arm 520b have been unfolded relative to each other. While minimizing a range of the above motion so as not to substantially positionally-deviate from the inner space IS of the housing 220, the ground-based transport apparatus 150 may bring the container 630 into the EFEM or the manual port. The ground-based transport apparatus 150 may input the container 630 the EFEM or the manual port in spite of the narrow space.

When the container 630 is not delivered to the EFEM and/or the manual port in the state in which the first arm 520a and the second arm 520b are unfolded relative to each other, the driving module 210 may further access the EFEM and/or manual port. Alternatively, a third arm embedded in the second body 510 may protrude outwardly to push the first arm 520a and the second arm 520b toward the EFEM and/or the manual port. When the manipulator module 240 further includes the third arm, the third arm may connect the second body 510 and the first arm 520a to each other.

A process of taking out the container 630 may be substantially similar and/or the same as inversely performing the handling sequence of the ground-based transport apparatus 150 described above with reference to FIGS. 19 to 22. Consequently, a repeated description thereof may be omitted for the sake of brevity.

The ground-based transport apparatus 150 has been described above with reference to FIGS. 3 to 22. The ground-based transport apparatus 150 may be constructed as a SCARA-mounted autonomous driving robot to directly transport the container between the semiconductor facilities. The ground-based transport apparatus 150 may directly transport the container to each of various types of facilities such as, but not limited to, article storage facilities and semiconductor manufacturing facilities. The ground-based transport apparatus 150 may transport the container to and/or from the facility in spite of a narrow space in the semiconductor manufacturing space. According to the present disclosure, transport automation of the container to and/or from various facilities may be implemented. Furthermore, the transport automation of the container to and from the facility in the narrow space may be implemented using a mobile robot.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical concept or characteristics of the present disclosure. Therefore, it may be appreciated that the embodiments as described above are not restrictive but illustrative in all respects.

What is claimed is:

1. A ground-based transport apparatus for transporting a container in a semiconductor manufacturing plant, the ground-based transport apparatus comprising:
a driving controller configured to move the ground-based transport apparatus on a ground of the semiconductor manufacturing plant;
a housing on the driving controller;
a shelf structure in the housing and comprising a plurality of shelves; and
a manipulator arm assembly in the housing and spaced apart from the shelf structure,
wherein the manipulator arm assembly is configured to:
remove the container from a first shelf of the plurality of shelves; and
set the container on a second shelf of the plurality of shelves, and
wherein the driving controller is further configured to:
transport the container between a plurality of facilities, each facility of the plurality of facilities comprising a substrate treating apparatus, the container storing a substrate; and
store the container in a ground-based storage apparatus disposed on the ground of the semiconductor manufacturing plant.

2. The ground-based transport apparatus of claim 1, wherein the driving controller comprises:
a code reader configured to identify an identification code attached to each facility of the plurality of facilities, and
wherein the driving controller is further configured to dock, using the identification code, the ground-based transport apparatus with a facility of the plurality of facilities.

3. The ground-based transport apparatus of claim 2, wherein the driving controller is further configured to scan, using the code reader, the identification code attached to an upper portion of a front surface plate of the facility, and
wherein the identification code comprises a plurality of vertical codes.

4. The ground-based transport apparatus of claim 3, wherein the driving controller is further configured to correct a docking posture of the ground-based transport apparatus with respect to the facility, based on an angle between a first line segment and a second line segment,
wherein the first line segment couples a first vertical code of the plurality of vertical codes of the identification code with a second vertical code of the plurality of vertical codes of the identification code, and
wherein the second line segment is parallel to a front surface of the driving controller.

5. The ground-based transport apparatus of claim 2, wherein the driving controller comprises:
a first distance measuring sensor configured to measure a first distance between the ground-based transport apparatus and a facility of the plurality of facilities; and
a second distance measuring sensor configured to measure a second distance between the ground-based transport apparatus and the facility,
wherein the second distance measuring sensor is adjacent to the first distance measuring sensor, and
wherein the driving controller is further configured to dock the ground-based transport apparatus with the facility based on the first distance and the second distance.

6. The ground-based transport apparatus of claim 5, wherein the driving controller is further configured to scan, using the code reader, the identification code attached to a side surface of a front surface plate of the facility, and
wherein the identification code comprises a single horizontal code.

7. The ground-based transport apparatus of claim 6, wherein the driving controller is further configured to correct a docking posture of the ground-based transport apparatus based on a value obtained by calculating a first measurement value of the first distance measuring sensor and a second measurement value of the second distance measuring sensor.

8. The ground-based transport apparatus of claim 6, wherein the driving controller is further configured to correct a docking posture of the ground-based transport apparatus based on an angle between a first line segment and a second line segment,
wherein the first line segment couples the first distance measuring sensor with the second distance measuring sensor, and
wherein the second line segment is parallel to a front surface of the front surface plate of the facility.

9. The ground-based transport apparatus of claim 1, further comprising:
a battery,
wherein the driving controller comprises a charging pad configured to charge the battery, and
wherein the driving controller is further configured to charge the battery, using the charging pad, when the manipulator arm assembly is performing at least one of removing the container from the first shelf or setting the container on the second shelf.

10. The ground-based transport apparatus of claim 1, wherein the housing comprises at least one open side surface.

11. The ground-based transport apparatus of claim 1, wherein each shelf of the plurality of shelves comprises:
a pin assembly configured to fix the container; and
a sensor configured to detect at least one of whether the container has been loaded on the shelf or whether the container is at a correct position,
wherein the pin assembly at least partially surrounds the sensor.

12. The ground-based transport apparatus of claim 11, wherein the pin assembly comprises:
a kinematic pin; and
an anti-vibration structure under the kinematic pin and configured to absorb vibration.

13. The ground-based transport apparatus of claim 1, further comprising an elastic structure between the driving controller and the housing configured to absorb an impact applied to the ground-based transport apparatus from an outside.

14. The ground-based transport apparatus of claim 1, wherein the manipulator arm assembly comprises:
a body;
a first arm pivotably coupled to the body;
a second arm pivotably coupled to the first arm; and
a hand installed at an end of the second arm.

15. The ground-based transport apparatus of claim 14, wherein the second arm is positioned at a different vertical level from a vertical level of the first arm.

16. The ground-based transport apparatus of claim 14, wherein the body is configured to move the first arm in a direction perpendicular to a pivoting direction.

17. The ground-based transport apparatus of claim 14, wherein the manipulator arm assembly is configured to perform at least one of removing the container from the first shelf or setting the container on the second shelf by performing a backward movement of the second arm, a pivot movement of the second arm, and a forward movement of the first arm.

18. A logistics processing system, comprising:
a substrate treating apparatus configured to treat a substrate;
an overhead storage apparatus configured to store a container storing the substrate, the overhead storage apparatus being installed on a ceiling of a semiconductor manufacturing plant;
a ground-based storage apparatus installed on a ground of the semiconductor manufacturing plant and configured to store the container;
an overhead transport apparatus configured to move along a rail installed on the ceiling of the semiconductor manufacturing plant and to transport the container; and
a ground-based transport apparatus configured to move on the ground of the semiconductor manufacturing plant and to transport the container,
wherein the ground-based transport apparatus comprises:
a driving controller configured to move the ground-based transport apparatus on the ground of the semiconductor manufacturing plant;
a housing on the driving controller;
a shelf structure in the housing and comprising a plurality of shelves; and
a manipulator arm assembly in the housing and spaced apart from the shelf structure,
wherein the manipulator arm assembly is configured to:
remove the container from a first shelf of the plurality of shelves; and
set the container on a second shelf of the plurality of shelves, and
wherein the driving controller is further configured to transport the container between a plurality of facilities and the ground-based storage apparatus, each facility of the plurality of facilities comprising the substrate treating apparatus.

19. The logistics processing system of claim 18, further comprising:
an interlayer transport apparatus configured to:
couple the ground of the semiconductor manufacturing plant with the ceiling of the semiconductor manufacturing plant; and
transport the container.

20. A ground-based transport apparatus for transporting a container in a semiconductor manufacturing plant, the ground-based transport apparatus comprising:
a driving controller configured to move the ground-based transport apparatus on a ground of the semiconductor manufacturing plant;
a housing on the driving controller;
a shelf structure in the housing and comprising a plurality of shelves; and
a manipulator arm assembly in the housing and spaced apart from the shelf structure,
wherein the manipulator arm assembly is configured to:
remove the container from a first shelf of the plurality of shelves; and
set the container on a second shelf of the plurality of shelves,
wherein the driving controller is configured to:
transport the container between a plurality of facilities, each facility of the plurality of facilities comprising a substrate treating apparatus, the container storing a substrate; and
store the container in a ground-based storage apparatus disposed on the ground of the semiconductor manufacturing plant,
wherein the driving controller comprises:
a code reader configured to identify an identification code attached to each facility of the plurality of facilities;
a first distance measuring sensor configured to measure a first distance between the ground-based transport apparatus and a facility of the plurality of facilities; and
a second distance measuring sensor configured to measure a second distance between the ground-based transport apparatus and the facility,
wherein the second distance measuring sensor is adjacent to the first distance measuring sensor,
wherein the driving controller is configured to dock the ground-based transport apparatus with the facility based on the identification code, the first distance, and the second distance,
wherein the identification code comprises at least one of a plurality of vertical codes attached to an upper portion of a front surface plate of the facility or a horizontal code attached to a side surface of the front surface plate of the facility,
wherein the driving controller is configured to:
based on the identification code comprising the plurality of vertical codes, correct a docking posture of the ground-based transport apparatus based on a first angle between a first line segment and a second line segment; and
based on the identification code comprising the horizontal code, correct the docking posture based on a second angle between a third line segment and a fourth line segment,
wherein the first line segment couples a first vertical code of the plurality of vertical codes with a second vertical code of the plurality of vertical codes,
wherein the second line segment is parallel to a front surface of the driving controller,
wherein the third line segment couples the first distance measuring sensor with the second distance measuring sensor, and
wherein the fourth line segment is parallel to the front surface of the front surface plate of the facility.
